(19) United States
(12) Patent Application Publication
(10) Pub. No.: US 2020/0035864 A1
(43) Pub. Date: Jan. 30, 2020

(54) LIGHT EMITTING DEVICE

(71) Applicant: COMMISSARIAT A L'ENERGIE ATOMIQUE ET AUX ENERGIES ALTERNATIVES, Paris (FR)

(72) Inventors: Bertrand CHAMBION, Poncharra (FR); Adrien GASSE, Seyssins (FR); Marion VOLPERT, Sassenage (FR)

(73) Assignee: COMMISSARIAT A L'ENERGIE ATOMIQUE ET AUX ENERGIES ALTERNATIVES, Paris (FR)

(21) Appl. No.: 16/472,037

(22) PCT Filed: Dec. 18, 2017
(86) PCT No.: PCT/FR2017/053637

§ 371 Date: Jun. 20, 2019

(30) Foreign Application Priority Data
Dec. 22, 2016 (FR) 16 63191

(51) Int. Cl. H01L 33/38; H01L 33/08; H01L 33/24

(52) U.S. Cl. CPC H01L 33/38; H01L 2933/0016; H01L 33/24; H01L 33/08

(57) ABSTRACT

The invention relates to a light-emitting device (100) comprising: at least one light-emitting structure (110) comprising a first side and a second side that are essentially parallel; a first electrode (160, 170) making contact, via a contact area, with either one of the first and second sides, the device being characterized in that the first electrode (160, 170) is shaped so as to cause a decrease in, from a first region and in the direction of at least one second region of the contact area, a current density that is liable to flow through the light-emitting structure (110).

### TECHNICAL FIELD

This invention relates to a light emitting device comprising at least one light emitting structure. More particularly, the at least one light emitting structure may be devoid of support substrate, and whose electrodes design makes it possible to homogenise the temperature of said diode during operation.

### Prior Art

FIG. 1 illustrates a known light emitting device 10 according to the state of the art. The device 10 comprises a plurality of light emitting devices 11 arranged in matrix form (n rows and m columns), resting on the front face of a thick support substrate 12, with a thickness of several tens of micrometres (for example 80 μm).

An interconnection layer 13, designed to address each light emitting diode or group of light emitting diodes 11 individually, is also formed on a back face of the thick support substrate 12, and connected to a control circuit through an interposer 14.

However, such a device is not satisfactory.

A thick support substrate imposes the formation of relatively deep trenches in said support substrate so as to electrically isolate said light emitting diodes. However, the formation of deep trenches is complicated in practice, and in particular makes it difficult to consider light emitting diodes smaller than 30 μm.

Furthermore, deep trenches are usually formed by a Deep Reactive Ion Etching (DRIE) step that is frequently too expensive.

Thus, in order to simplify the light emitting diode manufacturing method, it is envisaged a thinning or even a removal the support substrate making it possible to consider the formation of shallow trenches (for example with a depth of less than 10 μm), or even to manage without trenches at all.

However, a thick support substrate provides a thermomechanical function designed to limit temperature differences (thermal spreading) that can occur between the centre and the contour of a light emitting diode in operation, and the efficiency of which is closely related to its thickness. More particularly, thinning of the support substrate degrades its thermomechanical properties. For example, FIGS. 2a and 2b illustrate the temperature profile of light emitting diodes in operation, resting on a 80 μm support substrate and on a 5 μm support substrate respectively. In this context, an 80 μm thick support substrate limits the temperature difference between the centre C and the contour B of a diode to 7° C., while this difference is equal to 57° C. when the support substrate is thinned to 5 μm. Such a temperature difference can induce thermomechanical stresses in the light emitting diode, which can eventually degrade the performances of said diode.

Furthermore, a large temperature difference between the centre and the edge of a light emitting diode generates a difference in light intensity perceptible to the human eye, and degrades visual comfort when this difference in brightness exceeds 30%.

Thus, one purpose of this invention is to disclose a light emitting device comprising light emitting structures, and allowing the use of a support substrate less than 20 μm thick, and more particularly less than 10 μm thick, without degrading thermal management of said light emitting structures.

Another purpose of this invention is to disclose a light emitting device for which the manufacturing method is easier to implement that methods known according to the state of the art.

### PRESENTATION OF THE INVENTION

The purposes of this invention are at least partly achieved by a light emitting device comprising:
at least one light emitting structure comprising essentially parallel first and second faces,
a first electrode in contact, on a contact surface, with either the first face or the second face,

the device being characterised in that the first electrode is conformed to impose a decrease, from a first region and towards at least one second region of the contact surface, of a current density that can pass through the light emitting structure.

Contact means electrical contact.

First face means either the front face or the back face, and second face means the other among the front face and the back face.

It is obvious without saying that the first region and the second region are on the same contact surface.

A light emitting device means a device that comprises a light emitting structure, a first electrode and a second electrode. The first electrode makes electrical contact with one of the first and the second face, while the second electrode makes electrical contact with the other of the first and the second face. The presence of the second electrode is at least implicit, and therefore is not necessarily specified.

The decrease of the current density that can pass through the light emitting structure from the first region to at least one second region can thus reduce the temperature difference between said first and second regions and particularly within said light emitting structure.

In other words, this decrease in the current density can make the temperature of the light emitting structure uniform, more particularly when the light emitting device is located on a support structure thinner than 20 μm, or even thinner than 10 μm.

Consequently, there is no point in providing the device with a thick support substrate, for example more than a few tens of micrometres thick.

This invention contrasts with light emitting devices known in the state of the art for which the first and/or the second electrode(s) is (are) generally shaped to impose a uniform current density on the entire surface formed by one and/or the other among the first and second faces.

Besides, as soon as a plurality of light emitting structures is considered, there is no need for the formation of deep trenches (deep trenches refers to trenches with a depth of at least 10 μm). Trenches with a depth of less than 10 μm are sufficient to delimit and electrically isolate the light emitting structures.

Furthermore, shallow trenches also open up the possibility of the formation of smaller light emitting structures, for example with a side dimension smaller than 20 μm, or even smaller than 10 μm.

The contact surface comprises a centre and a contour, the first region comprising the centre of the contact surface, and the current density is advantageously maximum in the first region.

It is also obvious that the contact between the first electrode and either the first or the second face is made at least at the centre of said face.

According to one embodiment, the first electrode has a decreasing thickness profile along at least two opposite directions from the centre towards the contour of the contact surface.

In this case, it is assumed without it being necessary to specify it, that at least one second region is adjacent to the contour of the contact surface.

Two opposite directions means two directions in the plane formed by the contact surface. The two opposite directions also pass through the centre of said contact surface. It is also assumed throughout this description, without it being necessary to specify it, that although preferably parallel, the two opposite directions may have an angle deviation, for example an angle deviation of less than 20°.

More particularly, the thickness profile decreases along the two opposite directions starting from the centre towards the contour. It is also assumed that the maximum thickness of the first electrode is at the centre.

According to one embodiment, the thickness profile comprises steps parallel to one or the other of the first and the second face.

According to one embodiment, the thickness profile comprises a monotonous and continuous decrease.

According to one embodiment, the first electrode comprises at least one material chosen from among: Cu, Al, Ti, Ni, Ag, Pd, Pt, Rh, Au, In, a transparent conducting oxide, advantageously the transparent conducting oxide comprises at least one material chosen from among indium and tin oxide (ITO), zinc oxide (ZnO), gallium doped zinc oxide (GZO), indium and gallium doped zinc oxide (IGZO), aluminium doped zinc oxide (AZO), aluminium and gallium doped zinc oxide (AGZO), indium doped cadmium oxide, tin oxide (SnO₂).

Advantageously, the above-mentioned elements (metallic and transparent conducting oxide) can be used in the form of ink, for example with at least one component chosen from among: DEPOT-PSS (poly(3,4-ethylenedioxythiophene) and sodium polystyrene sulphonate, graphene, carbon nanotubes.

According to one embodiment, the first electrode comprises a material with a positive temperature coefficient, advantageously the material comprises at least one element chosen from among barium titanate ceramic, strontium titanate ceramic, lead titanate ceramic, tantalum nitride.

According to one embodiment, the first electrode has a textured metallic contact surface with one or the other of the first and the second face, the textured metallic contact surface comprising metallic contact regions and regions without metallic contact.

According to one embodiment, the density of metallic contact regions reduces from the first region towards the second region.

According to one embodiment, the regions without metallic contact are recesses formed in one or the other of the front and the back electrode.

According to one embodiment, the recesses are filled with a dielectric material, advantageously the dielectric material comprises at least one material chosen from among silicon dioxide, silicon nitride.

According to one embodiment, the metallic contact regions have a decreasing density from the centre towards the edge of the first or second face with which the first electrode is in contact.

According to one embodiment, the metallic contact regions are circular in shape.

According to one embodiment, the at least one light emitting structure comprises a light emitting layer from one of its first and second faces towards the other of the first and second faces, resting on a support substrate with a thickness of less than 10 μm, and advantageously less than 5 μm.

According to one embodiment, the light emitting layer comprises an active layer intercalated between a first semiconducting layer and a second semiconducting layer.

According to one embodiment, the active layer includes at least one material chosen from among: GaN, InGaN, InGaAs, InGaAlP, GaAs.

According to one embodiment, the light emitting layer comprises nanowires perpendicular to the front face.

According to one embodiment, the device comprises a plurality of light emitting structures arranged in matrix form.

The invention also relates to a method of sizing the first electrode that will be used in the light emitting device according to the invention, the light emitting device comprising at least one light emitting structure comprising essentially parallel first and second faces, the first electrode being in contact on a contact surface with the other among the first and second faces, the method including the following steps:

a) a step for determining the profile of a current density that will pass through one of the first and second faces, said current density profile being determined from a first region towards at least one second region of the contact surface;

b) a step for making the first electrode to create the current density profile in step a).

According to one embodiment, step a) for determining the current density profile is executed such that the temperature difference between the first and second regions is less than a predetermined temperature difference, advantageously the predetermined temperature difference is less than 20° C., even more advantageously it is less than 10° C., or even less than 5° C.

According to one embodiment, the adaptation step b) comprises adjustment of a thickness profile of the first electrode.

### BRIEF DESCRIPTION OF THE DRAWINGS

Other characteristics and advantages will become clear in the following description of the embodiments of the light emitting device according to the invention, given as non-limitative examples, with reference to the appended drawings in which:

FIG. 1 is a diagrammatic representation of a light emitting element known in prior art,

FIGS. 2a and 2b are graphic representations of the temperature profile (on the vertical axis, in “° C.”) of the front face of a light emitting diode as a function of the distance between the centre C of said diode (on the horizontal axis), more particularly, FIGS. 2a and 2b relate to a light emitting diode supported on a 80 μm thick substrate and a 5 μm thick substrate respectively,

FIG. 3a is a diagrammatic representation on a cross-section plane of a light emitting structure that can be implemented in the context of this invention,

FIG. 3b is a diagrammatic representation of a light emitting structure on a cross-section plane, comprising a plurality of nanowires extending perpendicular to the front face, and that can be implemented in the context of this invention,

FIGS. 4a and 4b are each diagrammatic representations of a light emitting device according to a first embodiment of this invention,

FIG. 5 is a graphic representation of the variation of resistance (along the vertical axis) as a function of the temperature (horizontal axis) of a material with a positive temperature coefficient that can be implemented in the framework of a second embodiment of the invention,

FIG. 6a is a simplified representation of a light emitting device according to a third embodiment of the invention,

FIG. 6B is a diagrammatic representation of a top view of a back electrode that can be implemented in the context of the third embodiment of this invention,

FIG. 7 is a diagrammatic cross-sectional representation of a light emitting device according to this invention, that can be implemented in a method of sizing one and/or the other of the front and back electrodes according to the invention,

FIG. 8 is a graphic representation of the variation of the current density (along the vertical axis) as a function of the distance from the centre (horizontal axis).

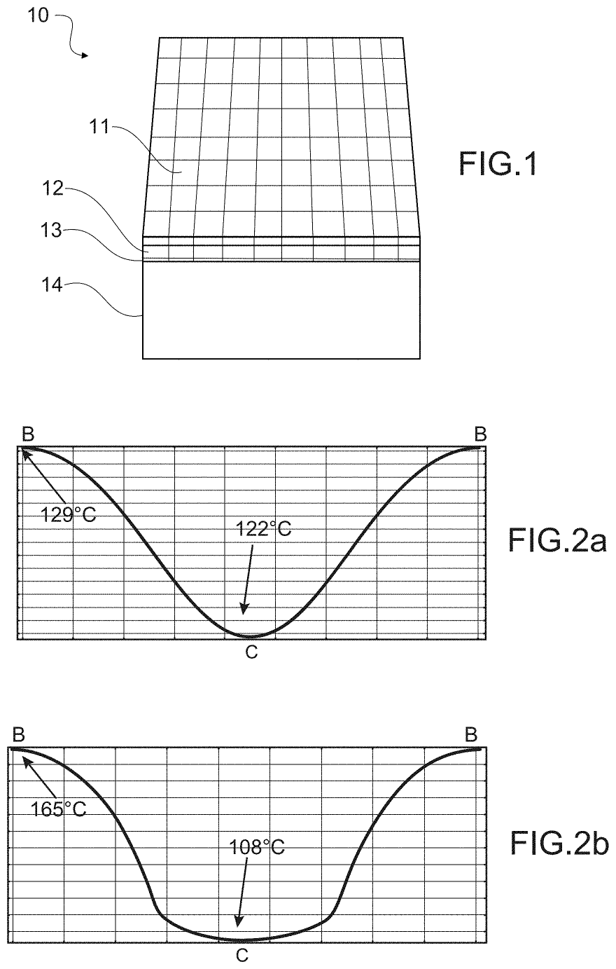

### DETAlLED PRESENTATION OF PARTICULAR EMBODIMENTS

The invention described in detail below implements a light emitting device comprising a light emitting structure for which thermal management is insured by a new electrode architecture (called the first electrode). According to the invention, the first electrode is adapted to impose a decrease in the current density passing through the light emitting structure from a first region to a second region of the contact surface between the electrode and the face concerned. More particularly, the maximum current density occurs at the first region of the contact surface, and decreases towards the second region. Thus, the architecture of the electrodes makes it possible to limit the temperature difference within the light emitting structure. More particularly, in one particular example of the invention that is described in detail in the remainder of the description, the architecture of the first electrode makes it possible to limit the increase of the temperature at the contour of the light emitting structure relative to its centre due to the Joule effect, without necessarily making use of a thick support substrate.

Note now that the first region as defined in this invention is a region in which the current density that can be injected into the light emitting device is the highest.

A light emitting device means a device that comprises a light emitting structure, a first electrode and a second electrode. The first electrode makes electrical contact with one of the first and the second face, while the second electrode makes electrical contact with the other of the first and the second face. The presence of the second electrode is at least implicit, and therefore is not necessarily specified.

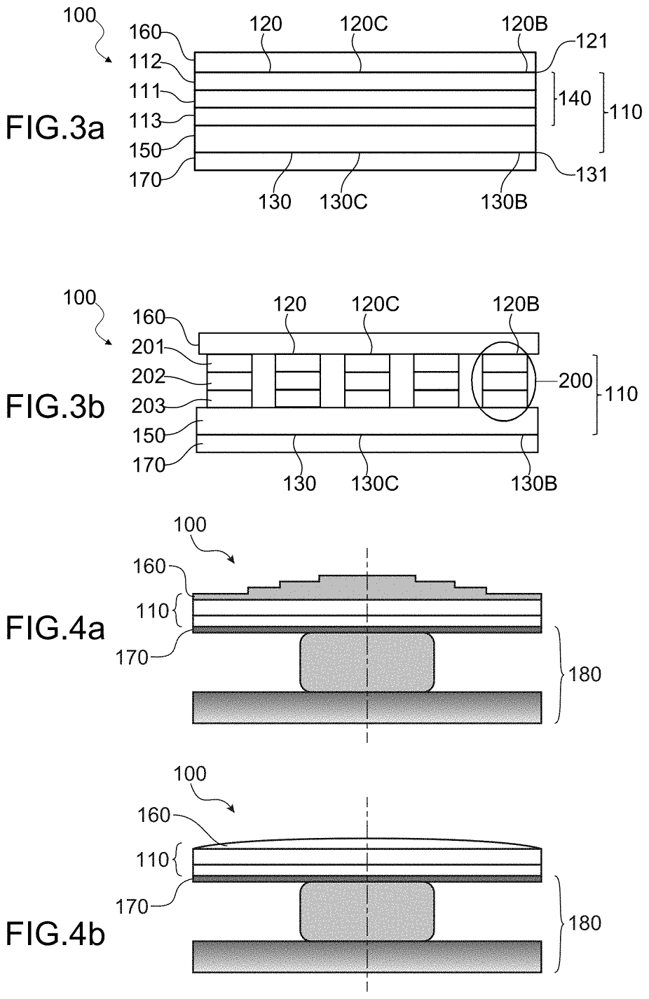

The light emitting device 100 according to this invention will now be described with reference to FIGS. 3, 4a, 4b, 5, 6a and 6b.

The light emitting device 100 comprises at least one light emitting structure 110.

The light emitting structure refers to a structure that emits light when a current passes through it.

The at least one light emitting structure may be square in shape, with a side dimension of between 3 and 400 μm.

The light emitting structure 100 (as illustrated in FIG. 3a) may comprise a plurality of light emitting structures 110 arranged, for example, in matrix form. A matrix form refers to a mesh with N rows and M columns. Each light emitting structure 110 is then arranged at the intersection of a row with a column of the mesh.

Two adjacent light emitting structures may be separated by a trench with a width of less than 3 μm, advantageously less than 1 μm.

The light emitting structure 110 comprises a first face 120 and a second face 130 essentially parallel to each other.

The front face of the light emitting structure is a face by which said structure is capable of emitting light radiation.

First face means either the front face or the back face, and second face means the other among the front face and the back face.

The first face 120 comprises a centre 120C and a contour 120B.

The second face 130 comprises a centre 130C and a contour 130B.

The centre of a face means the centre of gravity of said face.

The light emitting device 100 may be interfaced with an interposer through an electrode formed on the back face 130 of the light emitting structure 110 (said electrode is then called the back electrode).

An electrode in contact with the front face is called the front electrode. The contact surface between the front electrode and the front face is called the front contact surface.

An electrode in contact with the back face is called the back electrode. The contact surface between the back electrode and the back face is called the back contact surface.

The light emitting structure 110 may comprise, from its front face 120 to its back face 130, a light emitting layer 140 resting on a support substrate 150, the light emitting structure 110 having a thickness of less than 10 μm, and advantageously less than 5 μm.

For example, the support substrate 150 may contain silicon.

The light emitting layer 140 may include an active layer 111 intercalated between a first semiconductor layer 112 and a second semiconductor layer 113.

The first semiconductor layer 112 may include type n GaN (type n means doped with electron donor species).

The second semiconductor layer 113 may include type p GaN (type p means doped with hole donor species).

The active layer 111 may comprise at least one material chosen from among: GaN, GaAs, InGaN, InGaAlP.

The active layer 111, the first semiconducting layer 112 and the second semiconducting layer 113 may be formed by epitaxy techniques to deposit films on a substrate.

Formation of said layers makes use of techniques known from the skilled in the art and therefore will not be described in detail in this invention.

Trenches are also formed in films formed by epitaxy so as to delimit the light emitting structures 110 (this is referred to as “pixelisation”), but also in the substrate so as to electrically isolate said light emitting structures 110.

The substrate is then thinned to less than 20 μm, advantageously to less than 10 μm, and even more advantageously to less than 5 μm. Thinning techniques, and techniques to provide support by temporary substrates (also called “handles”) are known from the skilled in the art and therefore will not be described in detail herein.

Alternatively (as illustrated in FIG. 3b), the light emitting structure 110 may comprise nanowires 200 perpendicular to the front face. Each nanowire 200 may non-limitatively comprise a stack composed of a zone 201 of InGaN-n, an active zone 202, a zone 203 of GaN-p or InGaN-p.

In this respect, the skilled in the art may refer to patent application [1] mentioned at the end of the description, and more particularly from page 19 line 24 to page 20 line 10.

The set of nanowires in a light emitting structure 110 is advantageously supported on the support substrate 150.

The light emitting device 100 according to the invention also has a first electrode 160 adapted to impose a passage of a current (or current density) through the light emitting structure 110.

The contact surface 121, 131 of the first electrode 160, 170 is in contact, advantageously in direct contact, with one or the other of the first face 120 and the second face 130. The first electrode; 160, 170, is conformed to impose a decrease from a first region and towards at least one second region of the contact surface 121, 131, of a current density that can pass through the light emitting structure 110.

First and second regions refer to two regions belonging to the contact surface.

The contact surface comprises a centre and a contour.

The first region may include the centre (in which case we use the term central region) of the contact surface.

Advantageously, the current density may be maximum in the first region. In this case, the first region is in correspondence with a power supply contact for the front or back electrode considered. We will considerer that two elements are in correspondence when they are positioned one and the other on opposite faces of the electrode, and project one on the other along the thickness of said electrode.

Advantageously, the first electrode has a decreasing thickness profile along at least two opposite directions from the centre towards the contour of the contact surface.

We will limit the description to a first region of the contact surface that is coincident with the centre of the face or back considered. In this respect, in the remainder of this description we will use the terms first region and centre to mean the same thing.

Moreover, in the remainder of this description, the second region is assumed to be adjacent to the contour of the contact surface.

The skilled din the art, with his general knowledge and the description, will find it easy to generalise this invention to a first region that is not central, for example the first region may be adjacent to an edge of the contact surface.

More particularly, the first electrode is shaped to impose a decrease along at least two opposite directions starting from the centre towards the contour of the contact surface (in other words from the first region towards the second region), of a current density that can pass through said face, said current density also being maximum at the centre of said contact surface.

Thus, whenever the current density that can pass through the first face and/or the second face decreases from the centre towards the contour of said face, a reduction is observed in the difference of losses by the Joule effect at the centre and at the contour, compared with the difference observed in devices known in prior art. The result is thus better uniformity of the temperature of the light emitting structure 110.

According to a first embodiment, the thickness profile of the first electrode 160, 170 reduces from the centre towards the contour of the contact surface 121, 131. More particularly, the thickness profile decreases along the two opposite directions starting from the centre towards the contour.

According to this first embodiment, the first electrode can advantageously entirely cover either the first face 120 or the second face 130 of the light emitting structure 110.

For example, the thickness profile comprises steps parallel to either the first or the second face.

In this respect, FIG. 4a represents the light emitting device 100 provided with a first electrode (in this example on the front face) according to the invention and having a thickness profile reducing from the centre towards the contour in steps.

Such an electrode may be obtained by successive steps of masking by photolithography and etching of an electrode with approximately constant thickness.

Still according to the first embodiment, the thickness profile of the first electrode may decrease monotonously from the centre towards the contour (FIG. 4b). Fabrication of this electrode may include the following successive steps:

a) a step for depositing a layer of electrode material with a thickness of between 50 nm and 500 nm (for example 150 nm), on either the first face or the second face of the light emitting structure,

b) a step for depositing a layer of photo lithographic resin with a thickness of less than 10 μm, and advantageously less than 5 μm, on the layer of electrode material (for example the photo lithographic resin may be 2 μm),

c) a step for creeping the layer of photo lithographic resin at a temperature higher than the vitreous transition temperature Tg of said resin such that said resin layer has a monotonously and continuously decreasing thickness profile from the centre towards the contour,

d) a step for dry etching until the layer of photo lithographic resin is at least partially removed (the etching step can advantageously be done by an argon or oxygen plasma).

At the end of step d), the thickness profile of the electrode is conforming with the thickness profile of the layer of photo lithographic resin after the step c) for creeping.

Advantageously, the first electrode 160, 170 may comprise a transparent conducting oxide.

The transparent conducting oxide may comprise at least one material chosen from among indium and tin oxide (ITO), zinc oxide (ZnO), gallium doped zinc oxide (GZO), indium and gallium doped zinc oxide (IGZO), aluminium doped zinc oxide (AZO), aluminium and gallium doped zinc oxide (AGZO), indium doped cadmium oxide, tin oxide (SnO₂).

Also advantageously, the first electrode 160, 170 may comprise a metal.

The metal may comprise at least one metal chosen from among: Cu, Al, Ti, Ni, Ag, Pd, Pt, Rh, Au, In.

Advantageously, the above-mentioned elements (metallic and transparent conducting oxide) can be used in the form of ink, for example with at least one component chosen from among: DEPOT-PSS (poly(3,4-ethylenedioxythiophene) and sodium polystyrene sulphonate, graphene, carbon nanotubes.

According to this first embodiment, the thickness profile of the first electrode 160, 170 imposes a decrease in the current density passing through the light emitting structure, from the centre to the contour.

This decrease in the current density is accompanied by an increasingly uniform temperature within the light emitting structure, and also a reduction in the average temperature of the light emitting structure.

Furthermore, this invention makes it possible to also consider light emitting structures smaller than structures known in prior art.

Furthermore, the at least partial removal of the support substrate also makes it possible to envisage matrices of flexible light emitting structures.

According to a second embodiment, the first electrode 160, 170 may comprise a material with a positive temperature coefficient (in other words an electrode with a behaviour like a thermistance with positive coefficient), advantageously the material comprises at least one element chosen from among barium titanate ceramic, strontium titanate ceramic, lead titanate ceramic, tantalum nitride.

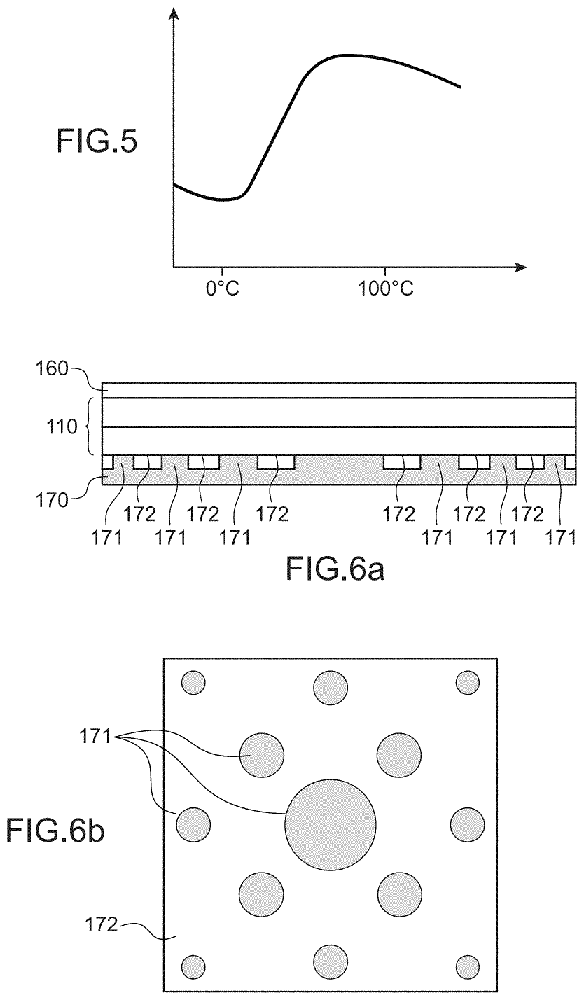

Such a material has variable resistivity when a temperature variation is applied to it (as presented in FIG. 5). More particularly, the electrical resistivity of said material increases with temperature in the operating temperature range considered of the device. Thus, an electrode, for example the front electrode, made of such a material self-regulates the current density passing through the light emitting structure as a function of the local temperature at the face of the light emitting structure with which it is in contact.

Advantageously, the thickness of the first electrode 160, 170 may be between 1 nm and 10 μm.

According to this second embodiment, the first electrode 160, 170 can advantageously entirely cover either the first face 120 or the second face 130 respectively of the light emitting structure 110.

FIGS. 6a and 6b illustrate an embodiment of a third embodiment of a first electrode placed on the back face of the light emitting structure (in this case, the first electrode is identified as a back electrode).

The skilled in the art, after seeing the technical information provided in this description, will find it easy to implement the third embodiment at the front electrode 160.

According to the third embodiment of the invention (FIGS. 6a and 6b), the first electrode 170 has a textured metallic contact surface with the first face 130 (identified as the back face), the textured metallic contact surface comprising metallic contact regions 171 and regions without metallic contact 172.

Textured metallic contact surface means a surface for which the metallic contact between an electrode and the face of the light emitting structure with which it is in contact is not homogeneous, in other words the metallic contact varies from the centre towards the edge.

Metallic contact means a contact adapted to allow current to pass from an electrode to the light emitting structure, and vice versa.

On the other hand, a region without a metallic contract will not allow the passage of current between an electrode and the light emitting structure.

Thus, according to this invention, the density of metallic contact regions 171 can reduce from the centre towards the contour of the back face 170.

Advantageously, regions without metallic contract 172 may include recesses formed in the back electrode 170.

A recess formed in the electrode means a cavity formed within the volume of said electrode and from its contact surface.

Recesses may be filled with a dielectric material.

For example, the dielectric material may comprise at least materials chosen from among silicon dioxide, silicon nitride.

The density of the metallic contact regions 171 may decrease from the centre towards the edge of the back face 130.

The metallic contact region 171 may be circular in shape (FIG. 6b).

The three embodiments presented can also be envisaged for the second electrode. In other words, the light emitting device may comprise a first electrode and a second electrode called the front electrode and the back electrode respectively (or conversely the back electrode and the front electrode), each located on a different face of the light emitting structure (the first and second faces). The front contact surface 121 of the front electrode 160 is in contact with the front face 120, while the back contact surface 131 of the back electrode 170 is in contact with the back face 130.

Also according to these three embodiments, and as an alternative to the above description, the second electrode is not in contact with an external face (in other words either the first or the second face), and brings the light emitting structure into contact via a though recess formed in the light emitting structure.

The invention also relates to a method of sizing the first electrode 160, 170.

The first electrode 160, 170 may advantageously be designed such that, during operation, the temperature difference between the centre and the edge of the light emitting structure 110 is less than a predetermined difference called the difference ΔT/T (ΔT being the difference in temperature between the centre and the contour along one of the two opposite directions, and T is the temperature at the centre of the front 120 or back 130 face concerned).

More particularly, the aim may be to size the first electrode 160, 170 appropriately to impose a particular profile of the current density along two opposite directions starting from the centre towards the contour of either the first or the second face. The particular profile of the current density corresponds to a ratio ΔJ/J (ΔJ being the difference in current density at the centre and at the contour along one of the two opposite directions, and J the current density at the centre of the front 120 or back 130 face concerned).

Thus, for a given light emitting device, it is possible to simulate or measure the difference ΔT/T of said device in operation. These techniques form part of general knowledge of the skilled in the art, and consequently are not described in this invention.

It is also possible to establish a relation between the difference ΔT/T and the ratio ΔJ/J.

For example, the method of sizing the first electrode 160, 170 may include the following steps:

a) a step for determining the profile of a current density that will pass through one of the first and second faces 160, 170, said current density profile being determined along at least two opposite directions starting from the centre towards the contour of either the first or the second face;

b) a step for making the first electrode 160, 170 to create the current density profile in step a).

Making the electrode means determining the geometric characteristics and choosing the material from which it is composed, to make the current density profile determined in step a).

More particularly, the step a) for determining the current density profile can be executed such that the temperature difference between the centre and the edge of either the first or the second region 120, 130 is less than a predetermined temperature difference, advantageously the predetermined temperature difference is less than 20° C., even more advantageously it is less than 10° C., and even more advantageously again less than 5° C.

Even more particularly, the step b) for making the electrode includes an adjustment of a thickness profile of the first electrode.

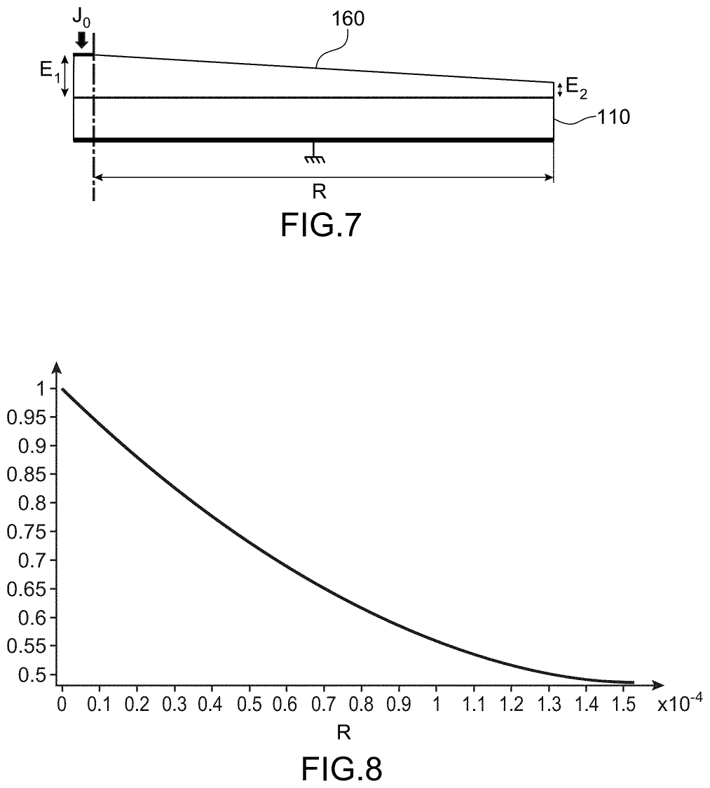

Thus for example, the light emitting diode illustrated in FIG. 7 comprises a 253 μm by 380 μm light emitting structure (only a half-structure is represented on FIG. 7). Therefore the diagonal of said structure is 456 μm (along direction R represented on FIG. 7).

The front electrode 160 is made of indium and tin oxide (with electrical resistivity equal to 3.12×10⁻⁶ ohm·m) with thickness E₂ at the contour equal to 100 nm. In the framework of a simulation, the thickness E₁ at the centre can be equal to the values given in the following table, and it varies linearly from the centre towards the contour (along direction R):

| Thickness of front | Current density |
|---|---|
| electrode at centre | at the contour |
| 200 nm | 0.48 J₀ |
| 300 nm | 0.57 J₀ |
| 400 nm | 0.64 J₀ |
| 500 nm | 0.68 J₀ |
| 600 nm | 0.72 J₀ |

J₀ (also denoted J(x=0)) being the current density at the centre of the front electrode 160.

The light emitting structure may include a layer of GaN with a thickness equal to 5 μm.

The variation of the current density J(x) along the direction of the diagonal of the front electrode 160 can then by simulated digitally (as a function of the distance x from the centre).

For example, it is known that the current density J(x) (along one of the two opposite directions) is given by the following relation:

$$J ( x ) = J ( x = 0 ) \cdot Exp ( - \frac{x}{{L}_{s}} )$$

In which

$${L}_{s} = \sqrt{( ( {ρ}_{c} + {ρ}_{p} {t}_{p} ) \frac{{ρ}_{electrode}}{{t}_{electrode}} )}$$

ρ_{c} being the resistance per unit area of the contact between the back electrode 170 and the GaN layer,

ρₚ being the resistivity of the material forming the back electrode 170 in the direction orthogonal to said electrode,

tₚ the thickness of the back electrode 170,

ρ_{electrode} the resistivity of the material forming the back electrode along the x direction,

t_{electrode} the length of the back electrode 170.

FIG. 8 shows an example of the variation of the current density J(x) (on the vertical axis) as a function of the distance from the centre x (along the horizontal axis), for a thickness at the centre of the front electrode equal to 200 nm, and J₀ represents the current density at the centre of the front electrode 160.

An exponential reduction in the current density can be clearly seen.

The current density profile obtained for each thickness is associated with a temperature difference between the centre and the edge of the face concerned (front or back).

The inventors have clearly observed that a ratio ΔJ/J at the contour to the current density at the centre equal to the order of 30% can obtain a difference in brightness between the centre and the contour equal to less than 30%.

### REFERENCES

[1] FR3012676

1. A light emitting device comprising:
at least one light emitting structure comprising an essentially parallel first face and second face,
a contact surface of a first electrode in contact with either the first face or the second face,
wherein the first electrode is conformed to impose a decrease, from a first region and towards at least one second region of the contact surface, of a current density that can pass through the light emitting structure,
the contact surface comprises a centre and a contour, the first region comprising the centre of the contact surface.

2. The device according to claim 1, wherein the first electrode has a decreasing thickness profile along at least two opposite directions from the centre towards the contour of the contact surface.

3. The device according to claim 2, wherein the thickness profile comprises steps parallel to one or the other of the first face and the second face.

4. The device according to claim 2, wherein the thickness profile comprises a monotonous and continuous decrease.

5. The device according to claim 1, wherein the first electrode has a textured metallic contact surface with one or the other of the first face and the second face, the textured metallic contact surface comprising metallic contact regions and regions without metallic contact.

6. The device according to claim 5, wherein the density of metallic contact regions reduces from the first region towards the second region.

7. The device according to claim 5, wherein the regions without metallic contact are recesses formed in the front and/or the back electrode.

8. The device according to claim 4, wherein the metallic contact regions are circular in shape.

9. The device according to claim 1, wherein the at least one light emitting structure comprises a light emitting layer from one of its first and second faces towards the other of the first and second faces, resting on a support substrate with a thickness of less than 10 μm, and advantageously less than 5 μm.

10. The device according to claim 9, wherein the light emitting layer comprises an active layer intercalated between a first semiconducting layer and a second semiconducting layer.

11. The device according to claim 9, in which the light emitting layer comprises nanowires perpendicular to the front face.

12. A method of sizing the first electrode that will be used in the light emitting device according to claim 1, the light emitting device comprising at least one light emitting structure comprising essentially parallel first and second faces, the first electrode being in contact on a contact surface with one or the other among the first and second faces, the method including the following steps:
a) a step for determining the profile of a current density that will pass through the first face and/or the second face, said current density profile being determined from a first region towards at least one second region of the contact surface;
b) a step for making the first electrode to reproduce the current density profile in step a).

13. The method according to claim 12, wherein step a) to determine the current density profile is executed such that the temperature difference between the first region and the second region is less than a predetermined temperature difference.

14. The method according to claim 12, wherein the adaptation step b) comprises adjustment of a thickness profile of the first electrode.
